(19) United States
(12) Patent Application Publication
(10) Pub. No.: US 2024/0305248 A1
(43) Pub. Date: Sep. 12, 2024

(54) LOW-NOISE AMPLIFIER WITH SEGMENTED CORE AND TUNABLE RESISTIVE FEEDBACK

(71) Applicant: Qorvo US, Inc., Greensboro, NC (US)

(72) Inventors: Jeppe Korshøj Bendixen, Vrå (DK); Christian Drud Larsen, Hjallerup (DK)

(21) Appl. No.: 18/583,407

(22) Filed: Feb. 21, 2024

Related U.S. Application Data
(60) Provisional application No. 63/536,162, filed on Sep. 1, 2023.
(60) Provisional application No. 63/489,309, filed on Mar. 9, 2023.

(51) Int. Cl. H03F 1/26; H03F 1/08; H03F 3/195

(52) U.S. Cl. CPC H03F 1/26; H03F 1/086; H03F 3/195; H03F 2200/294; H03F 2200/451

(57) ABSTRACT

Embodiments of a low noise amplifier (LNA) device and methods of operating the same are disclosed. In some embodiments, the LNA device includes an LNA input node, an LNA amplification core coupled to the LNA input node, and an LNA amplification core that includes LNA amplification segments. Each of the LNA amplification segments are configured to amplify the RF signal and are configured to be activated and deactivated. The LNA amplification core is configured to activate and deactivate the LNA amplification segments in accordance with the LNA core control input. A tunable feedback impedance is coupled between the LNA input node and the LNA amplification core. The tunable feedback impedance has a variable impedance that is set in accordance with the LNA core control input. The LNA amplification segments and the tunable feedback impedance are operated in a manner that optimizes KPIs depending on the input RF signal.

### RELATED APPLICATIONS

This application claims the benefit of provisional patent application Ser. No. 63/536,162, filed Sep. 1, 2023, which claims the benefit of provisional patent application Ser. No. 63/489,309, filed Mar. 9, 2023, the disclosures of which are hereby incorporated herein by reference in their entireties.

### FIELD OF THE DISCLOSURE

This disclosure relates generally to low noise amplifiers (LNAs) and methods of operating the same.

### BACKGROUND

In radio frequency (RF) front end circuitry, low noise amplifiers (LNAs) are commonly used to amplify wireless signals received on an antenna. As wireless technology evolves, the number and variations of wireless communications protocols increase and may encompass multiple operating modes. As such, LNAs sometimes need to be provided in high gain, medium gain, and low gain modes. Larger LNA amplification cores are advantageous in high gain modes while smaller LNA amplification cores are used in lower gain modes. Having multiple LNA amplification cores for each mode is expensive and complicated. Thus, simplified LNA cores that can operate in different modes are needed.

### SUMMARY

Embodiments of a low noise amplifier (LNA) device and methods of operating the same are disclosed. In some embodiments, the LNA device includes an LNA input node, an LNA amplification core coupled to the LNA input node, and an LNA amplification core that includes LNA amplification segments. Each of the LNA amplification segments is configured to amplify the RF signal and is configured to be activated and deactivated. The LNA amplification core is configured to activate and deactivate the LNA amplification segments in accordance with the LNA core control input. A tunable feedback impedance is coupled between the LNA input node and the LNA amplification core. The tunable feedback impedance has a variable impedance that is set in accordance with the LNA core control input. Accordingly, the LNA amplification device has an LNA amplification core that has different segments that are activated depending on the gain to be used to amplify the RF signal. The tunable feedback impedance insures that regardless of which of the segments is activated, the LNA amplification device maintains essentially the same input impedance.

In some embodiments, a low noise amplifier (LNA) device, includes: an LNA input node for receiving a radio frequency (RF) signal; an LNA amplification core coupled to the LNA input node, wherein: the LNA amplification core includes LNA amplification segments; each of the LNA amplification segments is configured to amplify the RF signal; each of the LNA amplification segments is configured to be activated and deactivated; the LNA amplification core is configured to activate and deactivate the LNA amplification segments in accordance with an LNA core control input; and a tunable feedback impedance coupled between the LNA input node and the LNA amplification core, the tunable feedback impedance has a variable impedance that is set in accordance with the LNA core control input. In some embodiments, the variable impedance of the tunable feedback impedance is set by the LNA core control input such that an input impedance at the LNA input node is such that all inband input return loss (IRL) is better that 10 dB and inband S11 for a given frequency band stays within the same quadrant of the Smith chart. In some embodiments, each LNA amplification segment of the LNA amplification segments includes: a different pair of field effect transistors (FETs), wherein the FETs in the pair of FETs are stacked; a different switch device that is coupled in shunt between the pair of FETs in the LNA amplification segment, wherein the LNA amplification segment is configured to be activated by the switch device such that the pair of FETs amplify the RF signal and is configured to be deactivated by the switch device such that the pair of FETs do not amplify the RF signal. In some embodiments, the LNA amplification core is coupled between a first node and a second node wherein, for each of the LNA amplification segments: each of the LNA amplification segments includes a different intermediary node; the switch device is coupled in shunt to the intermediary node; a first one of the pair of FETs has a first drain coupled to the first node and a first source coupled to the different intermediary node; a second one of the pair of the FETs has a second drain coupled to the intermediary node and a second source coupled to the second node. In some embodiments, a first gate of the first one of the pair of FETs in each of the LNA amplification segments is configured to receive a different bias voltage; a second gate of the second one of the pair of FETs in each of the LNA amplification segments is coupled to receive the RF input signal and is configured to receive a same bias voltage. In some embodiments, the tunable feedback impedance is connected between the first node and the LNA input node. In some embodiments, the LNA device further includes: an LNA output node that transmits the RF signal after amplification by the LNA amplification core; and an output matching impedance connected between the first node and the LNA output node. In some embodiments, the LNA device further includes a power node configured to receive a power voltage; an inductor coupled between the power node and the first node. In some embodiments, the LNA device further includes; a reference node configured to receive a reference voltage; an inductor coupled between the second node and the reference node. In some embodiments, the LNA core control input includes a control word having bits, wherein each bit of the bits in the control word determines whether a different one of the LNA amplification segments is activated or deactivated. In some embodiments, the tunable feedback impedance having a resistive device a first device terminal and a second resistive terminal; the tunable feedback impedance includes a resistive device includes resistive segments coupled between the first device terminal and the second device terminal; each resistive segment of the resistive segments includes a different resistor and a different switchable bypass path that is configured to bypass the resistor when activated and provide a resistance of the resistor between the first device terminal and the second device terminal when deactivated; each of bits is configured to cause a different one of the resistive segments to activate and deactivate the switchable bypass path for the resistive segment to thereby vary the variable impedance of the tunable feedback impedance.

In some embodiments, a low noise amplifier (LNA) device, includes: an LNA input node for receiving a radio frequency (RF) signal; an LNA amplification core coupled to the LNA input node, wherein: the LNA amplification core includes LNA amplification segments; each of the LNA amplification segments is configured to amplify the RF signal; each of the LNA amplification segments is configured to be activated and deactivated; the LNA amplification core is configured to activate and deactivate the LNA amplification segments in accordance with an LNA core control input; and a tunable feedback impedance coupled between the LNA input node and the LNA amplification core, the tunable feedback impedance has a variable impedance that is set such that an input impedance at the LNA input node is such that all inband input return loss (IRL) is better that 10 dB and inband S11 for a given frequency band stays within the same quadrant of the Smith chart. In some embodiments, each LNA amplification segment of the LNA amplification segments includes: a different pair of field effect transistors (FETs), wherein the FETs in the pair of FETs are stacked; a different switch device that is coupled in shunt between the pair of FETs in the LNA amplification segment, wherein the LNA amplification segment is configured to be activated by the switch device such that the pair of FETs amplify the RF signal and is configured to be deactivated by the switch device such that the pair of FETs do not amplify the RF signal. In some embodiments, the LNA amplification core is coupled between a first node and a second node wherein, for each of the LNA amplification segments: each of the LNA amplification segments includes a different intermediary node; the switch device is coupled in shunt to the intermediary node; a first one of the pair of FETs has a first drain coupled to the first node and a first source coupled to a different intermediary node; a second one of the pair of the FETs has a second drain coupled to the intermediary node and a second source coupled to the second node. In some embodiments, a first gate of the first one of the pair of FETs in each of the LNA amplification segments is configured to receive a different bias voltage; a second gate of the second one of the pair of FETs in each of the LNA amplification segments is coupled to receive the RF input signal and is configured to receive a same bias voltage. In some embodiments, the tunable feedback impedance is connected between the first node and the LNA input node. In some embodiments, the LNA device further includes: an LNA output node that transmits the RF signal after amplification by the LNA amplification core; and an output matching impedance connected between the first node and the LNA output node. In some embodiments, the LNA core control input includes a control word having bits, wherein each bit of the bits in the control word determines whether a different one of the LNA amplification segments is activated or deactivated. In some embodiments, the tunable feedback impedance having a resistive device a first device terminal and a second resistive terminal; the tunable feedback impedance includes a resistive device includes resistive segments coupled between the first device terminal and the second device terminal; each resistive segment of the resistive segments includes a different resistor and a different switchable bypass path that is configured to bypass the resistor when activated and provide a resistance of the resistor between the first device terminal and the second device terminal when deactivated; each of the bits is configured to cause a different one of the resistive segments to activate and deactivate the switchable bypass path for the resistive segment to thereby vary the variable impedance of the tunable feedback impedance.

In some embodiments, a method of providing low noise amplification to a radio frequency (RF) signal, includes: receiving a low noise amplifier (LNA) core control input; performing one or more of (a) activating one or more LNA amplification segments in an LNA amplification core in accordance with the LNA core control input, and (b) deactivating one or more of the LNA amplification segments in the LNA amplification core in accordance with the LNA core control input to provide activated set of one or more of the LNA amplification segments; tuning a variable impedance of a tunable feedback impedance coupled between an LNA input node and the LNA amplification core in accordance with the LNA core control input; receiving the RF signal at the LNA input node; and amplifying the RF signal with the activated set of one or more LNA amplification segments.

In some embodiments, a user element includes a low noise amplifier (LNA) device, the LNA includes: an LNA input node for receiving a radio frequency (RF) signal; an LNA amplification core coupled to the LNA input node, wherein: the LNA amplification core comprises LNA amplification segments; each of the LNA amplification segments is configured to amplify the RF signal; each of the LNA amplification segments is configured to be activated and deactivated; the LNA amplification core is configured to activate and deactivate the LNA amplification segments in accordance with an LNA core control input; and a tunable feedback impedance coupled between the LNA input node and the LNA amplification core, the tunable feedback impedance has a variable impedance that is set in accordance with the LNA core control input.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a low noise amplifier (LNA) device, in accordance with some embodiments;

FIG. 2 is an LNA amplification core, in accordance with some embodiments;

FIG. 3 is a variable resistive device, in accordance with some embodiments;

FIG. 4 and FIG. 5 are Smith Charts that show the effect of using resistive feedback to re-align input return losses (IRL) in the LNA amplification device of FIG. 1 as a result of a change in the number of active LNA amplification segments, in accordance with some embodiments;

FIG. 6A and FIG. 6B are Smith Charts wherein the LNA is used in 3 steps where, in G0-G2 modes, all of the LNA amplification segments are active, in G3-G4 modes, some of the LNA amplification segments are active, and, in G5-G7 modes, one of the LNA amplification segments are active without and with tunable resistive feedback respectively;

FIG. 7 is a flow diagram of a method of providing low noise amplification to the RF signal, in accordance with some embodiments; and

FIG. 8 illustrates a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

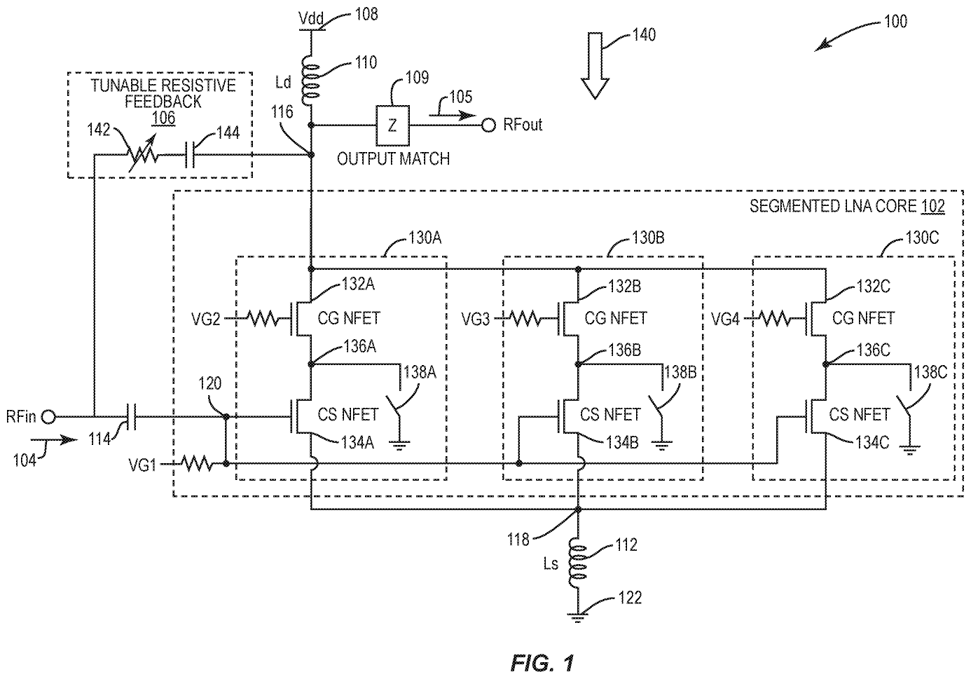

FIG. 1 is a low noise amplifier (LNA) device 100, in accordance with some embodiments.

In some embodiments, the LNA device 100 is provided in a front-end module of a user equipment (not explicitly shown), such as a smartphone, tablet, or laptop. The LNA device 100 have several modes of operation that correspond to the modes of operation of front-end circuitry of the user equipment. Each mode of operation of the LNA device has different key performance indicators (KPIs) for optimal performance in the user equipment. The KPIs include: gain, noise figure, linearity (IIP3), and current consumption. In some embodiments, the LNA device 100 is configured to keep input return loss (IRL) and output return loss (ORL) substantially constant. The LNA device 100 is configured to tune its KPIs for better performance within the user equipment. More specifically, the LNA device 100 gives a better system performance by trading off different KPIs at different modes by using a segmented LNA core and countering the change in IRL using resistive feedback, as explained in further detail below.

The LNA device 100 is configured to amplify a radio frequency (RF) signal 104. In some embodiments, the RF signal 104 is a receive signal received from an antenna (not explicitly shown) of the user equipment. The LNA device 100 is configured to provide low noise amplification to the RF signal 104. After amplification by the LNA device 100, the amplified RF signal 105 is transmitted to downstream circuitry so as to demodulate the amplified RF signal and extract data from the output RF signal 105.

In FIG. 1, the LNA device 100 includes an LNA input node RFin and an LNA output node RFout. The LNA device 100 is configured to receive the RF signal 104 at the LNA input node RFin and output the amplified RF signal 105 from the LNA output node RFout. The LNA device 100 also includes an LNA amplification core 102, a tunable feedback impedance 106, a power terminal 108, an output matching impedance 109, an inductor 110, an inductor 112 and a capacitor 114.

The LNA amplification core 102 is configured to receive the RF signal 104 from the LNA input node RFin. The LNA amplification core 102 is coupled between a node 116 and a node 118. In this embodiment, the node 116 operates as a feedback node. More specifically, the tunable feedback impedance 106 is connected between the node 116 and the LNA input node RFin. The capacitor 114 is connected between the LNA input node RFin and the input node 120 of the LNA amplification core 102. The LNA amplification core 102 is configured to amplify the RF signal 104, wherein the amplified RF signal 105 is then output from the node 116. The power terminal 108 is configured to receive a power voltage Vdd. In some embodiments, the power voltage Vdd is a regulated power voltage. In some embodiments, the power voltage Vdd is a power source voltage from a power source (e.g., battery). The inductor 110 is coupled between the power node 108 and the node 116. The inductor 110 blocks RF signal to the power terminal 108. The inductor 112 is connected between the node 118 and a reference node 122. The reference node 122 is configured to receive a reference voltage. In this embodiment, the reference node 122 is a ground node and the reference voltage is a ground voltage. The inductor 112 block RF signals to the reference node 122. Inductors 110 and 112 are also part of the frequency match of the LNA device 100.

When the RF signal 104 at the LNA input node RFin has low input power, the LNA amplification core 102 is configured to operate with a high gain and low noise figure. The high gain and low noise figure are important KPIs for overall system performance. When the RF signal 104 at the LNA input node RFin has high input power, the LNA amplification core 102 is configured to operate with a low gain. Low gain is important in maintaining low current consumption and high IIP3, which are more important KPIs for overall system performance in this situation. In some embodiments, a KPI is an input signal power range, wherein the input signal power range is from a thermal noise floor to about −10 dBm. In some embodiments, another example of a KPI is a gain range, wherein the gain range is from 21 dB to −15 dB. In some embodiments, a KPI is an Idd range, wherein the Idd range is from 15 mA to 2 mA. However, it should be noted that these are simply exemplary and that the KPIs may depend strongly on application and ADC ranges. Exemplary KPIs are listed above.

In order to provide a single LNA device that simultaneously meets all KPIs at both high and low gain modes, the LNA amplification core 102 of the LNA device 100 is segmented and the LNA device 100 includes the tunable feedback impedance 106. The segmentation of the LNA device 100 allows the LNA device 100 to switch from high to low gain modes. However, switching from high to low gain modes can change the input impedance of the LNA device 100 as seen at the LNA input node RFin. Accordingly, the tunable resistive feedback is tuned in the different modes so as to maintain the input impedance at the LNA input node RFin substantially the same in the different modes of operation.

In FIG. 1, the LNA amplification core 102 includes LNA amplification segments 130A, 130B, 130C. The LNA amplification core 102 includes three LNA amplification segments 130A, 130B, 130C. In other embodiments, the LNA amplification core 102 includes two or more LNA amplification segments. Each of the LNA amplification segments 130A, 130B, 130C are configured to be activated and deactivated. In higher gain modes, more of the LNA amplification segments 130A, 130B, 130C are activated and for lower gain modes less of the LNA amplification segments 130A, 130B, 130C are activated. In one embodiment, there are gains states 0-9. For gain states 0-2, all of the LNA amplification segments 130A, 130B, 130C are active. For gain state 3-4, the LNA amplification segments 130A, 130B are active and the LNA amplification segment 130C is deactivated. For gain states 5-7, the LNA amplification segment 130B is active and the LNA amplification segments 130A, 130C are deactivated.

The LNA amplification segment 130A includes a common gate field effect transistor (FET) 132A and a common source FET 134A. In FIG. 1, the common gate FET 132A and the common source FET 134A are each N-channel FETs (NFETs). A gate of the common gate FET 132A is configured to receive a bias gate voltage VG2. The drain of the common gate FET 132A is coupled to the node 116. A source of the common gate FET 132A is coupled to an intermediary node 136A. A drain of the common source FET 134A is coupled to the intermediary node 136A. A source of the common source FET 134A is coupled to the node 118. The gate of the common source FET 134A is coupled through the capacitor 114 to the LNA input node RFin to receive the RF signal 104 at the input node 120. The gate of the common source FET 134A is also configured to receive a bias voltage VG1. A switch device 138A is connected in shunt to the intermediary node 136A. Accordingly, in response to the switch device 138A being closed, the LNA amplification segment 130A is deactivated. In response to the switch device 138A being opened, the LNA amplification segment 130A is activated.

The LNA amplification segment 130B includes a common gate FET 132B and a common source FET 134B. In FIG. 1, the common gate FET 132B and the common source FET 134B are each N-channel FETs (NFETs). A gate of the common gate FET 132B is configured to receive a bias gate voltage VG3. The drain of the common gate FET 132B is coupled to the node 116. A source of the common gate FET 132B is coupled to an intermediary node 136B. A drain of the common source FET 134B is coupled to the intermediary node 136B. A source of the common source FET 134B is coupled to the node 118. The gate of the common source FET 134B is coupled through the capacitor 114 to the LNA input node RFin to receive the RF signal 104 at the input node 120. The gate of the common source FET 134B is also configured to receive the bias voltage VG1. A switch device 138B is connected in shunt to the intermediary node 136B. Accordingly, in response to the switch device 138B being closed, the LNA amplification segment 130B is deactivated. In response to the switch device 138B being opened, the LNA amplification segment 130B is activated.

The LNA amplification segment 130C includes a common gate FET 132C and a common source FET 134C. In FIG. 1, the common gate FET 132C and the common source FET 134C are each NFETs. A gate of the common gate FET 132C is configured to receive a bias gate voltage VG4. The drain of the common gate FET 132C is coupled to the node 116. A source of the common gate FET 132C is coupled to an intermediary node 136C. A drain of the common source FET 134C is coupled to the intermediary node 136C. A source of the common source FET 134C is coupled to the node 118. A gate of the common source FET 134C is coupled through the capacitor 114 to the LNA input node RFin to receive the RF signal 104 at the input node 120. The gate of the common source FET 134C is also configured to receive a bias voltage VG1. A switch device 138C is connected in shunt to the intermediary node 136C. Accordingly, in response to the switch device 138C being closed, the LNA amplification segment 130C is deactivated. In response to the switch device 138C being opened, the LNA amplification segment 130C is activated.

Each of the LNA amplification segments 130A, 130B, 130C includes a different pair of the FETs (132A, 134A), (132B, 134B), (132C, 134C). The FETs (132A, 134A), (132B, 134B), (132C, 134C) are stacked since the source of the FETs (132A, 132B, 132C) are coupled to the drain of the FETs (134A, 134B, 134C). The different switch device (138A, 138B, 138C) is coupled in shunt between the pair of the FETs (132A, 134A), (132B, 134B), (132C, 134C) in the LNA amplification segment 130A, 130B, 130C. For each of the LNA amplification segments 130A, 130B, 130C, the LNA amplification segment 130A, 130B, 130C is configured to be activated by the switch device (138A, 138B, 138C) such that the pair of FETs (132A, 134A), (132B, 134B), (132C, 134C) amplify the RF signal 102 and is configured to be deactivated by the switch device (138A, 138B, 138C) such that the pair of the FETs (132A, 134A), (132B, 134B), (132C, 134C) do not amplify the RF signal 104. In this manner, different LNA amplification segments 130A, 130B, 130C can be activated and deactivated to amplify the RF signal 104. As such, for each of the LNA amplification segment 130A, 130B, 130C, the LNA amplification segment 130A, 130B, 130C is configured to be activated by the switch device 138A, 138B, 138C such that the pair of the FETs (132A, 134A), (132B, 134B), (132C, 134C) amplify the RF signal 104 and is configured to be deactivated by the switch device 138A, 138B, 138C such that the pair of the FETs (132A, 134A), (132B, 134B), (132C, 134C) do not amplify the RF signal 104.

Each of the LNA amplification segments 130A, 130B, 130C includes the different intermediary node 136A, 136B, 136C. The switch device 138A, 138B, 138C of each of the LNA amplification segments 130A, 130B, 130C is coupled in shunt to the intermediary node 136A, 136B, 136C. The FET 132A, 132B, 132C of each of the LNA amplification segments 130A, 130B, 130C has a drain coupled to the node 116 and first source coupled to the intermediary node 136A, 136B, 136C of the LNA amplification segments 130A, 130B, 130C. The FET 134A, 134B, 134C of each of the LNA amplification segments 130A, 130B, 130C has a drain coupled to the intermediary node 136A, 136B, 136C of the LNA amplification segments 130A, 130B, 130C and a source coupled to the node 118. A gate of the FET 132A, 132B, 132C of each of the LNA amplification segments 130A, 130B, 130C is configured to receive a different bias voltage VG2, VG3, VG4. A gate of the FET 134A, 134B, 134C of each of the LNA amplification segments 130A, 130B, 130C is coupled to receive the RF signal 104 and is configured to receive the same bias voltage VG1.

The LNA output node RFout transmits the amplified RF signal 105 after amplification by the LNA amplification core 102. The output matching impedance 109 is connected between the node 116 and the LNA output node RFout. The output matching impedance 109 is configured to provide an impedance to match the impedance of the LNA device 100 at the LNA output node RFout to the load impedance at the LNA output node RFout. In some embodiments, the output match also varies. However, the output match is primarily used for tuning the LNA device 100 to different frequency bands. Nevertheless, some minor changes to ORL can be obtained if needed.

The LNA device 100 is configured to receive an LNA core control input 140. The LNA amplification segments 130A, 130B, 130C are activated and deactivated in accordance with the LNA core control input 140. In some embodiments, the LNA core control input 140 corresponds to different modes of the front-end circuitry that the LNA device 100 has put in. Thus, the LNA amplification segments 130A, 130B, 130C are activated and deactivated in accordance to what mode the front-end circuitry is operating in.

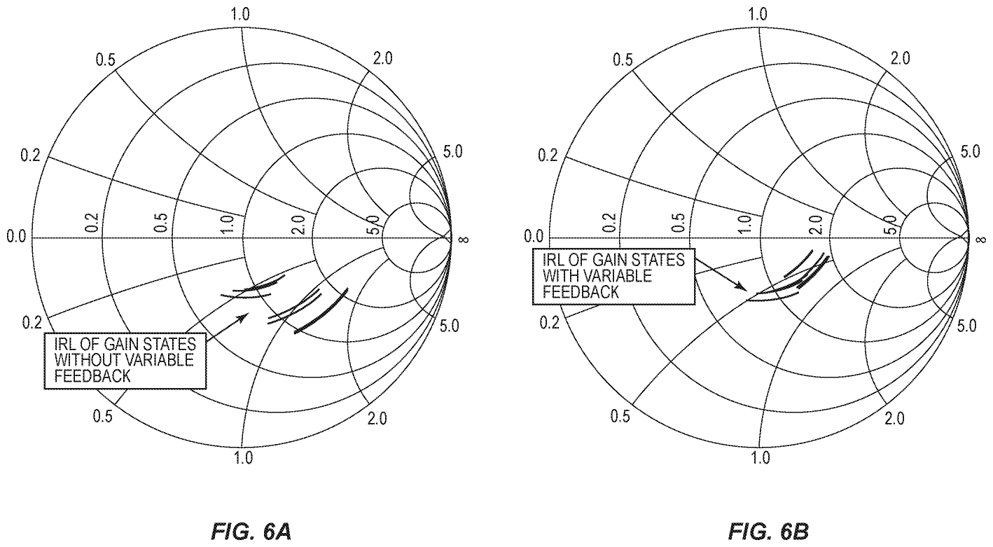

As the different LNA amplification segments 130A, 130B, 130C are activated and deactivated, the input impedance at the RF input terminal RFin can change. The tunable feedback impedance 106 has a variable impedance that is set by the LNA core control input 140 such that the input impedance at the LNA input node RFin stays substantially equal regardless of which of the LNA amplification segments 130A, 130B, 130C that are activated and deactivated. How this is met practically is application dependent. In some embodiments, the IRL as a dot in the smith chart is best, the smaller the area the better and within the same quadrant. The IRL of FIG. 6B is better than the IRL of FIG. 6A. In some embodiments, the base value for variance of the input impedance depends on an input filter impedance. All inband IRL (|dB|) are better than 10 dB and inband S11 for a given frequency band stays within the same quadrant of the Smith chart. Additionally, in some embodiments, inband S11 in smith chart for a given frequency band should overlay as much as possible across gain states. The node 116 is therefore a feedback node as the tunable feedback impedance 106 is connected between the node 116 and the LNA input node RFin.

In FIG. 1, the tunable feedback impedance 106 includes a variable resistive device 142 and a capacitor 144 connected in series. The variable resistive device 142 has a variable resistance that can be varied in order to vary the variable impedance of the tunable feedback impedance 106. In this embodiment, the capacitor 144 is a fixed capacitor. In other embodiments, the capacitor is a variable capacitor with a variable capacitance that can be varied. The impedance can also be variable using components in a combination of series and shunt configuration which a combination of fixed and variable components. In other embodiments, the tunable feedback impedance 106 includes a fixed or a variable impedance. Furthermore, in other embodiments, the tunable feedback impedance 106 may have any arrangement suitable for matching the input impedance.

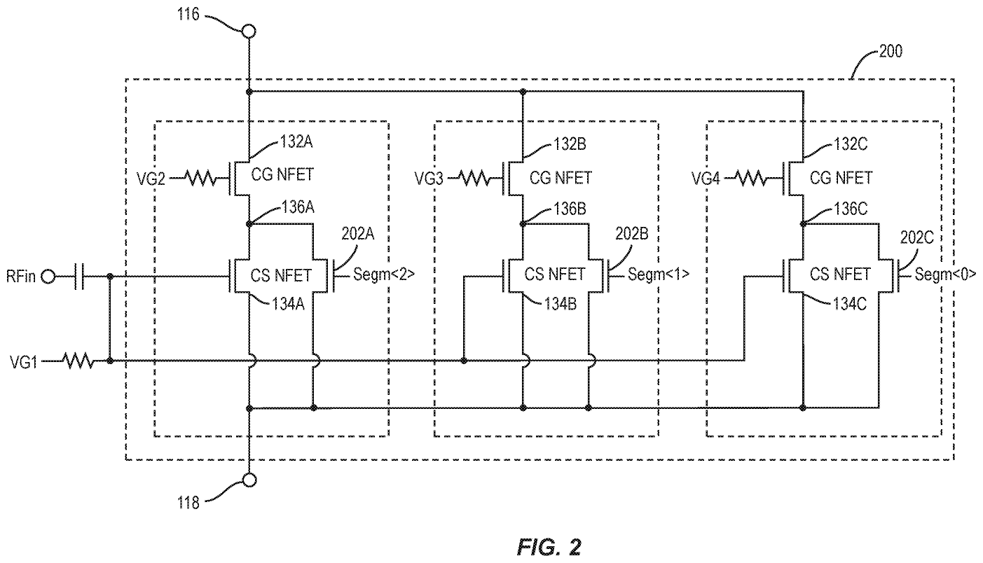

FIG. 2 is an LNA amplification core 200, in accordance with some embodiments.

The LNA amplification core 200 is an embodiment of the LNA amplification core 102, shown in FIG. 1. The LNA amplification core 200 has the same configuration and thus the same components in the LNA amplification core 200 and the LNA amplification core 102 will not be discussed here. In FIG. 2, a switch device 202A corresponds with the switch device 138A of FIG. 1. In FIG. 2, a switch device 202B corresponds with the switch device 138B of FIG. 1. In FIG. 2, a switch device 202C corresponds with the switch device 138C of FIG. 1.

In FIG. 2, the LNA core control input 140 (See FIG. 1) is a control word that includes three bits Segm<2>, Segm<1>, Segm<0>. Each of the three bits Segm<2>, Segm<1>, Segm<0> is received by a different one of the switch devices 202A, 202B, 202C. With regard to the switch device 202A, the switch device 202A is an NFET. A drain of the switch device 202A is connected to the intermediary node 136A. When the bit Segm<2> is in a low voltage state, the switch device 202A is deactivated. When the bit Segm<2> is in a high voltage state, the switch device 202A is activated. In this manner, the LNA amplification segment 130A is activated and deactivated depending on the voltage state of the bit Segm<2>.

With regard to the switch device 202B, the switch device 202B is a NFET. A drain of the switch device 202B is connected to intermediary node 136B. When the bit Segm<1> is in a low voltage state, the switch device 202B is deactivated. When the bit Segm<1> is in a high voltage state, the switch device 202B is activated. In this manner, the LNA amplification segment 130B is activated and deactivated depending on the voltage state of the bit Segm<1>.

With regard to the switch device 202C, the switch device 202C is an NFET. A drain of the switch device 202C is connected to intermediary node 136C. When the bit Segm<0> is in a low voltage state, the switch device 202B is deactivated. When the bit Segm<0> is in a high voltage state, the switch device 202C is activated. In this manner, the LNA amplification segment 130C is activated and deactivated depending on the voltage state of the bit Segm<0>.

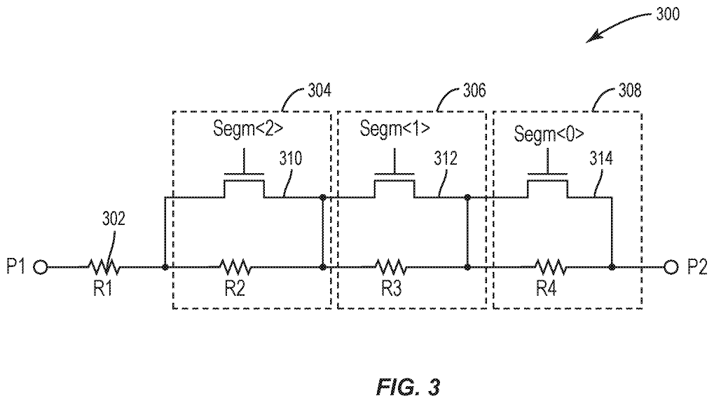

FIG. 3 is a variable resistive device 300, in accordance with some embodiments.

The variable resistive device 300 is configured to provide a variable resistance. More specifically, the variable resistive device 300 has a first device terminal P1 and a second resistive terminal P2. The resistive device 300 has resistive segments 302, 304, 306, 308 coupled between the first device terminal P1 and the second device terminal P2. The resistive segment 302 includes the resistor R1 and is connected to the first resistive terminal P1. The resistive segment 304 is connected between the resistive segment 302 and the resistive segment 306. The resistive segment 306 is connected between the resistive segment 304 and the resistive segment 308. The resistive segment 308 is connected to the second resistive terminal P2.

With respect to the resistive segments 304, 306, 308, each of the resistive segments 304, 306, 308 includes a different resistor R2, R3, R4, and a different switchable bypass path 310, 312, 314. The switchable bypass path 310 includes a FET that is configured to receive the bit Segm<2> (See also FIG. 2.) so that the FET is activated and deactivated in accordance with the bit Segm<2>. In response to the FET in the switchable bypass path 310 being turned on, a resistance of the resistor R2 is bypassed. In response to the FET in the switchable bypass path 310 being activated, a resistance of the resistor R2 is provided between the resistive terminals P1, P2.

The switchable bypass path 312 includes a FET, wherein the FET is configured to receive the bit Segm<1> (See also FIG. 2.) so that the FET is activated and deactivated in accordance with the bit Segm<1>. In response to the FET in the switchable bypass path 312 being turned on, a resistance of the resistor R3 is bypassed. In response to the FET in the switchable bypass path 312 being activated, a resistance of the resistor R3 is provided between the resistive terminals P1, P2.

The switchable bypass path 314 includes a FET that is configured to receive the bit Segm<0> (See also FIG. 2.) so that the FET is activated and deactivated in accordance with the bit Segm<0>. In response to the FET in the switchable bypass path 314 being turned on, a resistance of the resistor R4 is bypassed. In response to the FET in the switchable bypass path 312 being activated, a resistance of the resistor R4 is provided between the resistive terminals P1, P2. By utilizing the control word bits Segm<2>, Segm<1>, Segm<0> to introduce or bypass the resistances R2, R3, R4, the resistance of the resistive device 300 is varied in accordance to which LNA amplification segments 130A, 130B, 130C are activated and deactivated.

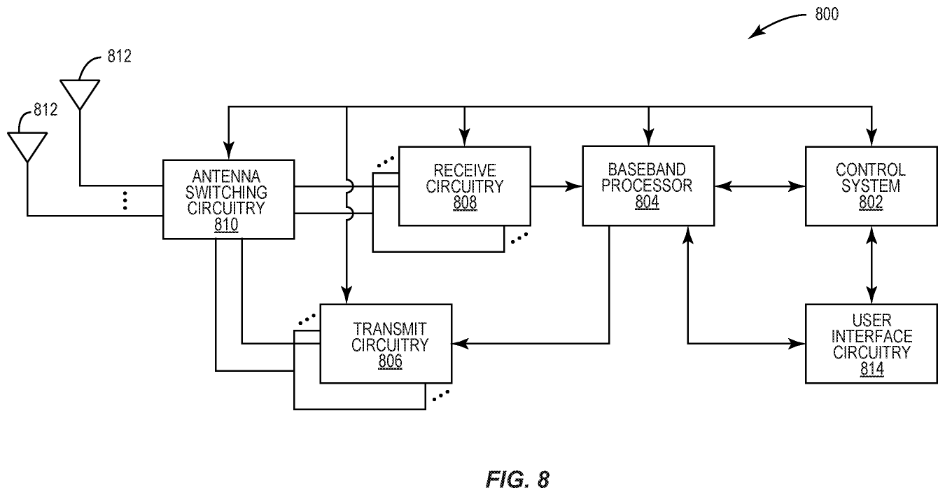

In some embodiments, control of the segmented LNA amplification core 200 and the variable resistive device 300 (i.e., tunable feedback impedance 300) is done using the same control bits segm<2>, segm<1>, segm<0> or by using different control bits Ina_segm<2>, Ina_segm<1>, Ina_segm<0>, fb_segm<2>, fb_segm<1>, fb_segm<0> from the control system 802 (See FIG. 8). In other embodiments, the number of control bits used for the segmented LNA amplification core 200 and the variable resistive device 300 are different.

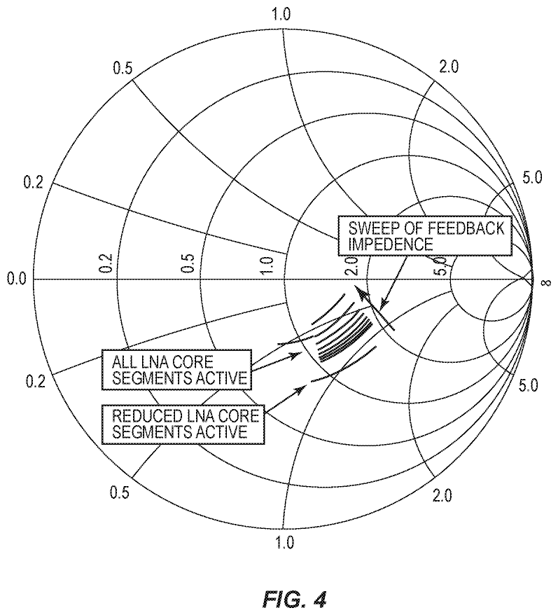

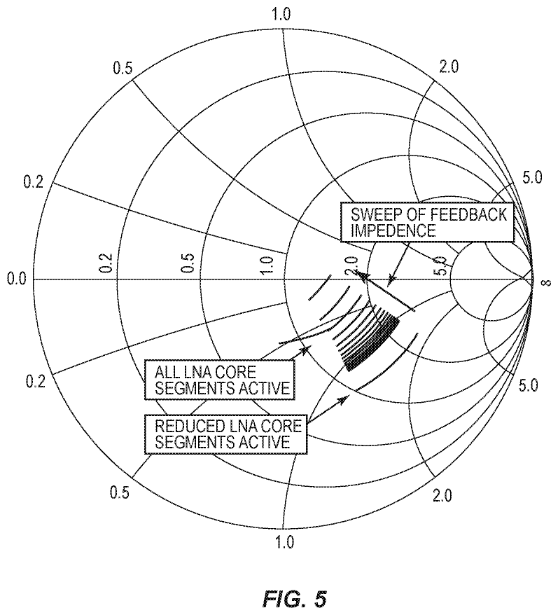

FIG. 4 and FIG. 5 are Smith Charts that shows the effect of using resistive feedback to re-align IRL in the LNA amplification device 100 as a result of a change of number of the active LNA amplification segments 130A, 130B, 130C, in accordance with some embodiments.

The reference IRL for best matching to the receive filter is with all of the LNA amplification segments 130A, 130B, 130C active (here G2 mode). G3 mode disables a number of segments of the LNA amplification segments 130A, 130B, 130C, and the IRL moves ‘out’ in the Smith chart. Thus, matching to the receive filter changes between G2 and G3, which changes transfer function of the receive filter, which again may degrade the system performance. By adding resistive feedback, the IRL can be re-aligned very close to the reference IRL. Thus, recreating a good match to the receive filter and restoring good system performance. G5 mode (See FIG. 5) disables more of the LNA amplification segments 130A, 130B, 130C and the IRL moved further out in the Smith Chart. As the shift in the IRL from an even smaller LNA core is greater, then a smaller resistance is needed to re-align the IRL.

FIG. 6A and FIG. 6B are Smith Charts wherein the LNA is used in 3 steps and, in G0-G2 modes, all of the LNA amplification segments 130A, 130B, 130C are active, in G3-G4 modes, some of the LNA amplification segments 130A, 130B, 130C are active, and, in G5-G7 modes, one of the LNA amplification segments 130A, 130B, 130C is active. As shown, with the tunable feedback impedance 106, the IRL becomes centered at the same area of the smith chart enabling a much-improved match to the receive filter.

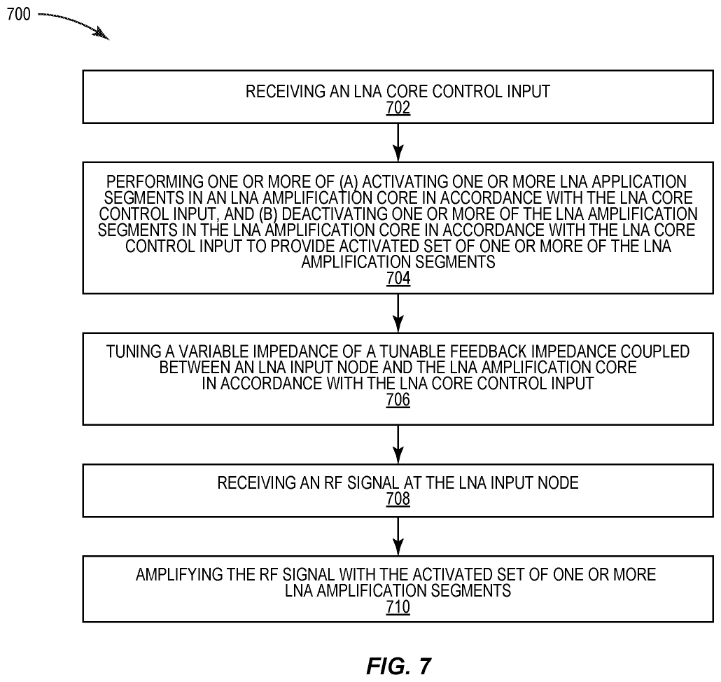

FIG. 7 is a flow diagram 700 of a method of providing low noise amplification to the RF signal 104, in accordance with some embodiments.

In some embodiments, the flow diagram 700 is performed by the LNA device 100 shown in FIG. 1. The flow diagram 700 includes blocks 702-708. Flow begins at the block 702.

At the block 702, an LNA core control input is received. An example of the LNA core control input is the LNA core control input 140 in FIG. 1. Flow then proceeds to the block 704.

At the block 704, one or more of (a) activating one or more LNA amplification segments in an LNA amplification core in accordance with the LNA core control input, and (b) deactivating one or more of the LNA amplification segments in the LNA amplification core in accordance with the LNA core control input is performed to provide activated set of one or more of the LNA amplification segments. An example of the LNA amplification core is the LNA amplification core 104 shown in FIG. 1. An example of the LNA amplification segments is the LNA amplification segments 130A-130C in FIG. 1. Flow then proceeds to the block 706.

At the block 706, a variable impedance of a tunable feedback impedance coupled between an LNA input node and the LNA amplification core in accordance with the LNA core control input. An example of the LNA input node is the LNA input node RFin shown in FIG. 1. An example of the tunable feedback impedance is the tunable feedback impedance 106 in FIG. 1. Flow then proceeds to the block 708.

At the block 708, an RF signal is received at the LNA input node. Flow then proceeds to the block 710.

At the block 710, the RF signal is amplified with the activated set of one or more LNA amplification segments.

With reference to FIG. 8, the concepts described above may be implemented in various types of user elements 800, such as mobile terminals, smart watches, tablets, computers, navigation devices, access points, and like wireless communication devices that support wireless communications, such as cellular, wireless local area network (WLAN), Bluetooth, and near field communications.

The user element 800 will generally include a control system 802, a baseband processor 804, transmit circuitry 806, receive circuitry 808, antenna switching circuitry 810, multiple antennas 812, and user interface circuitry 814. In a non-limiting example, the control system 802 may be a field-programmable gate array (FPGA) or an application-specific integrated circuit (ASIC). In this regard, the control system 802 may include at least a microprocessor(s), an embedded memory circuit(s), and a communication bus interface(s). The receive circuitry 808 receives radio frequency signals via the antennas 812 and through the antenna switching circuitry 810 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 804 processes the digitized received signal to extract the information or data bits conveyed in the received signal. This processing typically comprises demodulation, decoding, and error correction operations, as will be discussed in greater detail below. The baseband processor 804 is generally implemented in one or more digital signal processors (DSPs) and application specific integrated circuits (ASICs).

For transmission, the baseband processor 804 receives digitized data, which may represent voice, data, or control information, from the control system 802, which it encodes for transmission. The encoded data is output to the transmit circuitry 806, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 812 through the antenna switching circuitry 810. The multiple antennas 812 and the replicated transmit and receive circuitries 806, 808 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A low noise amplifier (LNA) device, comprising:
an LNA input node for receiving a radio frequency (RF) signal;
an LNA amplification core coupled to the LNA input node, wherein:
the LNA amplification core comprises LNA amplification segments;
each of the LNA amplification segments is configured to amplify the RF signal;
each of the LNA amplification segments is configured to be activated and deactivated; and
the LNA amplification core is configured to activate and deactivate the LNA amplification segments in accordance with an LNA core control input; and
a tunable feedback impedance coupled between the LNA input node and the LNA amplification core, the tunable feedback impedance has a variable impedance that is set in accordance with the LNA core control input.

2. The LNA device of claim 1, wherein the variable impedance of the tunable feedback impedance is set by the LNA core control input such that an input impedance at the LNA input node is such that all inband input return loss (IRL) is greater than 10 dB and inband S11 for a given frequency band stays within a same quadrant of a Smith chart.

3. The LNA device of claim 1, wherein each LNA amplification segment of the LNA amplification segments comprises:
a different pair of field effect transistors (FETs), wherein the FETs in the pair of FETs are stacked; and
a different switch device that is coupled in shunt between the pair of FETs in the LNA amplification segment, wherein the LNA amplification segment is configured to be activated by the switch device such that the pair of FETs amplify the RF signal and is configured to be deactivated by the switch device such that the pair of FETs does not amplify the RF signal.

4. The LNA device of claim 3, wherein the LNA amplification core is coupled between a first node and a second node wherein, for each of the LNA amplification segments:
each of the LNA amplification segments includes a different intermediary node;
the switch device is coupled in shunt to the intermediary node;
a first one of the pair of FETs has a first drain coupled to the first node and a first source coupled to the intermediary node; and
a second one of the pair of the FETs has a second drain coupled to the intermediary node and a second source coupled to the second node.

5. The LNA device of claim 4, wherein:
a first gate of the first one of the pair of FETs in each of the LNA amplification segments is configured to receive a different bias voltage; and
a second gate of the second one of the pair of FETs in each of the LNA amplification segments is coupled to receive the RF signal and is configured to receive a same bias voltage.

6. The LNA device of claim 4, wherein the tunable feedback impedance is connected between the first node and the LNA input node.

7. The LNA device of claim 4, further comprising:
an LNA output node that transmits the RF signal after amplification by the LNA amplification core; and
an output matching impedance connected between the first node and the LNA output node.

8. The LNA device of claim 7, further comprising:
a power node configured to receive a power voltage; and
an inductor coupled between the power node and the first node.

9. The LNA device of claim 4, further comprising:
a reference node configured to receive a reference voltage; and
an inductor coupled between the second node and the reference node.

10. The LNA device of claim 1, wherein the LNA core control input comprises a control word having bits, wherein each bit of the bits in the control word determines whether a different one of the LNA amplification segments is activated or deactivated.

11. The LNA device of claim 10, wherein:
the tunable feedback impedance having a resistive device, a first device terminal, and a second resistive terminal;
the tunable feedback impedance comprises the resistive device comprising resistive segments coupled between the first device terminal and the second resistive terminal;
each resistive segment of the resistive segments includes a different resistor and a different switchable bypass path that is configured to bypass the resistor when activated and provide a resistance of the resistor between the first device terminal and the second resistive terminal when deactivated; and
each bit of the bits is configured to cause a different one of the resistive segments to activate and deactivate the switchable bypass path for the resistive segments to thereby vary the variable impedance of the tunable feedback impedance.

12. A low noise amplifier (LNA) device, comprising:
an LNA input node for receiving a radio frequency (RF) signal;
an LNA amplification core coupled to the LNA input node, wherein:
the LNA amplification core comprises LNA amplification segments;
each of the LNA amplification segments is configured to amplify the RF signal;
each of the LNA amplification segments is configured to be activated and deactivated; and
the LNA amplification core is configured to activate and deactivate the LNA amplification segments in accordance with an LNA core control input; and
a tunable feedback impedance coupled between the LNA input node and the LNA amplification core, the tunable feedback impedance has a variable impedance that is set such that an input impedance at the LNA input node is such that all inband input return loss (IRL) is greater than 10 dB and inband S11 for a given frequency band stays within a same quadrant of a Smith chart.

13. The LNA device of claim 12, wherein each LNA amplification segment of the LNA amplification segments comprises:
a different pair of field effect transistors (FETs), wherein the FETs in the pair of FETs are stacked; and
a different switch device that is coupled in shunt between the pair of FETs in the LNA amplification segment, wherein the LNA amplification segment is configured to be activated by the switch device such that the pair of FETs amplifies the RF signal and is configured to be deactivated by the switch device such that the pair of FETs does not amplify the RF signal.

14. The LNA device of claim 13, wherein the LNA amplification core is coupled between a first node and a second node wherein, for each of the LNA amplification segments:
each of the LNA amplification segments includes a different intermediary node;
the switch device is coupled in shunt to the intermediary node;
a first one of the pair of FETs has a first drain coupled to the first node and a first source coupled to a different intermediary node; and
a second one of the pair of the FETs has a second drain coupled to the intermediary node and a second source coupled to the second node.

15. The LNA device of claim 14, wherein:
a first gate of the first one of the pair of FETs in each of the LNA amplification segments is configured to receive a different bias voltage; and
a second gate of the second one of the pair of FETs in each of the LNA amplification segments is coupled to receive the RF signal and is configured to receive a same bias voltage.

16. The LNA device of claim 14, wherein the tunable feedback impedance is connected between the first node and the LNA input node.

17. The LNA device of claim 14, further comprising:
an LNA output node that transmits the RF signal after amplification by the LNA amplification core; and
an output matching impedance connected between the first node and the LNA output node.

18. The LNA device of claim 12, wherein the LNA core control input comprises a control word having bits, wherein each bit of the bits in the control word determines whether a different one of the LNA amplification segments is activated or deactivated.

19. The LNA device of claim 18, wherein:
the tunable feedback impedance having a resistive device, a first device terminal, and a second resistive terminal;
the tunable feedback impedance comprises the resistive device comprising resistive segments coupled between the first device terminal and the second resistive terminal;
each resistive segment of the resistive segments includes a different resistor and a different switchable bypass path that is configured to bypass the resistor when activated and provide a resistance of the resistor between the first device terminal and the second resistive terminal when deactivated; and
each bit of the bits is configured to cause a different one of the resistive segments to activate and deactivate the switchable bypass path for the resistive segment to thereby vary the variable impedance of the tunable feedback impedance.

20. A method of providing low noise amplification to a radio frequency (RF) signal, comprising:
receiving a low noise amplifier (LNA) core control input;
performing one or more of (a) activating one or more of the LNA amplification segments in an LNA amplification core in accordance with the LNA core control input, and (b) deactivating one or more of the LNA amplification segments in the LNA amplification core in accordance with the LNA core control input to provide an activated set of one or more of the LNA amplification segments;
tuning a variable impedance of a tunable feedback impedance coupled between an LNA input node and the LNA amplification core in accordance with the LNA core control input;
receiving the RF signal at the LNA input node; and
amplifying the RF signal with the activated set of one or more of the LNA amplification segments.

21. A user element comprising a low noise amplifier (LNA) device, the LNA device comprising:
an LNA input node for receiving a radio frequency (RF) signal;
an LNA amplification core coupled to the LNA input node, wherein:
the LNA amplification core comprises LNA amplification segments;
each of the LNA amplification segments is configured to amplify the RF signal;
each of the LNA amplification segments is configured to be activated and deactivated; and
the LNA amplification core is configured to activate and deactivate the LNA amplification segments in accordance with an LNA core control input; and
a tunable feedback impedance coupled between the LNA input node and the LNA amplification core, the tunable feedback impedance has a variable impedance that is set in accordance with the LNA core control input.
